(19) United States
(12) Patent Application Publication
(10) Pub. No.: US 2026/0082608 A1
(43) Pub. Date: Mar. 19, 2026

(54) SEMICONDUCTOR STRUCTURE OF HIGH ELECTRON MOBILITY TRANSISTOR AND MANUFACTURING METHOD THEREOF

(71) Applicant: HiPer Semiconductor Inc., Cayman Islands (KY)

(72) Inventor: PO-JUNG LIN, Zhubei City (TW)

(21) Appl. No.: 19/296,041

(22) Filed: Aug. 11, 2025

(30) Foreign Application Priority Data
Sep. 19, 2024 (TW) 113135572

(51) Int. Cl. H10D 30/01; H10D 30/47; H10D 62/85; H10D 62/854

(52) U.S. Cl. CPC H10D 30/015; H10D 30/475; H10D 62/8503; H10D 62/854

(57) ABSTRACT

A semiconductor structure of a high electron mobility transistor and a manufacturing method thereof, wherein the method includes the following steps: depositing a barrier layer on the channel layer; depositing a doped control layer on the barrier layer; performing a preflow in the chamber of a first doping source gas containing a metal dopant for a predetermined time; depositing a doped stabilization layer on the doped control layer, both the doped stabilization layer and the doped control layer contain the metal dopant, wherein the metal dopant in the doped stabilization layer has a first doping concentration in a range from 1E19 cm⁻³ to 3E19 cm⁻³, and the metal dopant in the doped control layer has a second doping concentration in a range from 5E17 cm⁻³ to 1E19 cm⁻³; depositing a gate metal on the doped stabilization layer to form the semiconductor structure of the high electron mobility transistor.

### BACKGROUND

### 1. Technical Field

The present invention relates to a semiconductor structure of a high electron mobility transistor (HEMT) and a method of manufacturing the same. More particularly, the present invention relates to a semiconductor structure of a HEMT manufactured using a preflow process to improve conductivity and reduce the diffusion effect of a metal dopant.

### 2. Description of the Related Art

Please refer to FIG. 1, which is a schematic diagram illustrating the diffusion behavior of a metal dopant in the conventional manufacturing method of a semiconductor structure. For an enhancement-mode (E-mode) high electron mobility transistor (HEMT), a p-type doped gallium nitride (GaN) layer determines the threshold voltage (Vth) characteristics of the HEMT. Currently, manufacturing processes use p-type metal dopants such as magnesium (Mg) to enhance the electrical performance of the HEMT. However, as shown in FIG. 1, during the manufacture process, the concentration of a metal dopant in the chamber must reach a sufficiently high level (e.g., 1.5E19 cm⁻³) to maintain the conductivity of the p-type doped GaN. It takes time for the metal dopant concentration in the chamber to reach the target level (as indicated in region S1). During the period in which the concentration of the metal dopant gradually increases to the sufficiently high level to enable effective p-type doping of gallium nitride (GaN), a delay phenomenon may occur (as indicated in region S3). This delay results in an insufficient hole concentration in the grown p-type doped GaN layer. Furthermore, during the process in which the metal dopant concentration in the chamber reaches the target level, the metal dopant may diffuse into the barrier layer (AlGaN) located beneath the p-type doped gallium nitride (GaN) layer (as indicated in region S2), thereby affecting device performance. Conventional methods for growing p-type doped gallium nitride (GaN) layers often result in an excessively high concentration of metal dopant in the barrier layer. For example, the metal dopant concentration in the barrier layer may reach up to 2E18 cm⁻³, which adversely affects the threshold voltage (Vth) stability of the high electron mobility transistor (HEMT). Therefore, there is a need for a new fabrication technique to address the problems associated with the prior art.

### SUMMARY

The objective of the present invention is to provide a method for manufacturing a semiconductor structure of a high electron mobility transistor (HEMT), wherein a preflow process is employed to rapidly achieve a desired concentration of metal dopants within the chamber. This enhances the electrical performance of the HEMT and reduces the diffusion effect of the metal dopants.

Another object of the present invention is to provide a method for manufacturing a semiconductor structure of a high electron mobility transistor, wherein a preflow process is used to quickly raise the concentration of a metal dopant in the chamber to a target level, thereby improving the electrical characteristics of the doped stabilization layer and reducing the diffusion effect of the metal dopants.

To achieve the above objectives, the method for manufacturing a semiconductor structure of a high electron mobility transistor (HEMT) according to the present invention is performed in a chamber and includes the following steps:
depositing a barrier layer on a channel layer; depositing a doped control layer on the barrier layer;
performing a preflow in the chamber of a first doping source gas containing a metal dopant for a predetermined time; after the predetermined time, depositing a doped stabilization layer on the doped control layer, wherein both the doped stabilization layer and the doped control layer contain the metal dopant, wherein the metal dopant in the doped stabilization layer has a first doping concentration in a range from 1E19 cm⁻³ to 3E19 cm⁻³, and the metal dopant in the doped control layer has a second doping concentration in a range from 5E17 cm⁻³ to 1E19 cm⁻³; and depositing a gate metal on the doped stabilization layer to form the semiconductor structure of the high electron mobility transistor.

According to one embodiment of the present invention, the first doping source gas is Cp2Mg, and the predetermined time is from 10 seconds to 240 seconds.

According to one embodiment of the present invention, prior to the preflow of the first doping source gas containing the metal dopant into the chamber for the predetermined time, the doped control layer is an undoped gallium nitride (GaN) layer.

The present invention further provides a semiconductor structure of a high electron mobility transistor (HEMT) manufactured by the above-mentioned method, wherein a thickness of the doped stabilization layer is greater than a thickness of the doped control layer.

The present invention utilizes a preflow procedure to rapidly increase the concentration of the first doping source gas containing the metal dopant in the chamber to a range between 1E19 cm⁻³ and 3E19 cm⁻³ prior to the growth of the doped stabilization layer, thereby facilitating the growth of the doped stabilization layer. In addition, the doped control layer effectively withstands the diffusion of the metal dopant from the doped stabilization layer, thereby reducing the impact of the dopant on the barrier layer and improving the electrical performance of the high electron mobility transistor.

### BRIEF DESCRIPTION OF THE DRAWINGS

FIG. 1 is a schematic diagram illustrating the diffusion behavior of a metal dopant in the manufacturing method of a conventional semiconductor structure.

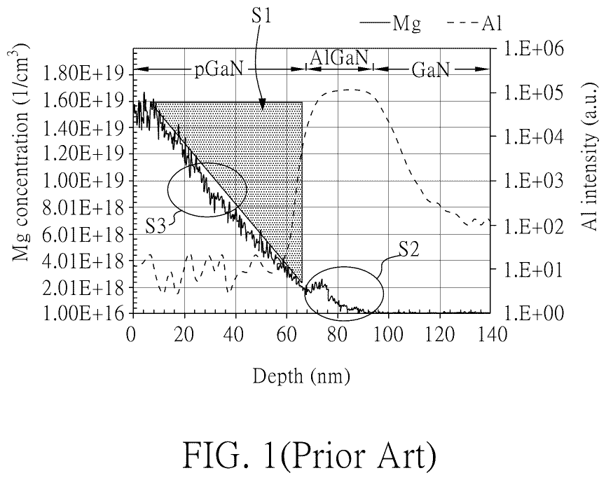

FIG. 2 is a flowchart illustrating the steps of a first embodiment of the method for manufacturing a semiconductor structure according to the present invention.

FIG. 3 is a schematic diagram illustrating the preflow procedure in the chamber.

FIG. 4 is a schematic diagram of a semiconductor structure of a high electron mobility transistor according to a first embodiment of the present invention.

FIG. 5 is a schematic diagram illustrating the diffusion behavior of a metal dopant in the method for manufacturing a semiconductor structure according to the present invention.

FIG. 6 is a flowchart illustrating the steps of a second embodiment of the method for manufacturing a semiconductor structure according to the present invention.

FIG. 7 is a schematic diagram illustrating the supply of a second doping source gas into the chamber.

FIG. 8 is a flowchart illustrating the steps of a third embodiment of the method for manufacturing a semiconductor structure according to the present invention.

FIG. 9 is a schematic diagram of a semiconductor structure of a high electron mobility transistor according to a second embodiment of the present invention.

### DETAILED DESCRIPTION OF THE EMBODIMENTS

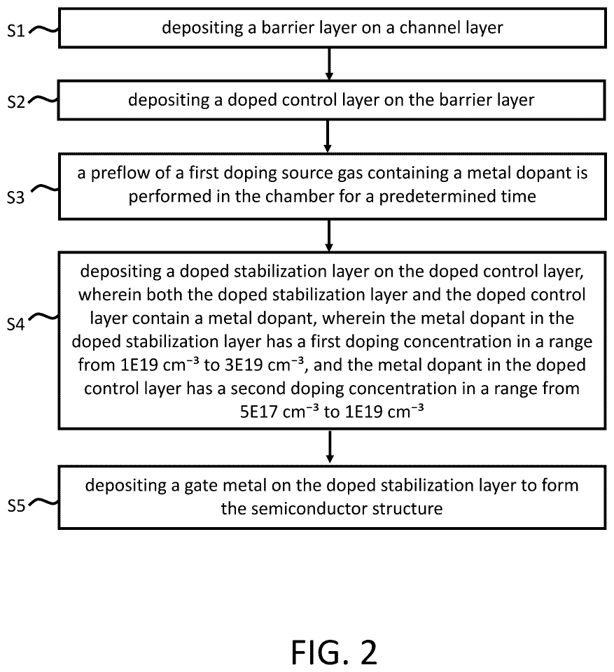

To better understand the technical content of the present invention, a preferred embodiment is described below. Please refer to FIGS. 2 to 5, which respectively illustrate: a step flowchart of a first embodiment of the method for manufacturing a semiconductor structure according to the present invention, a schematic diagram of the preflow procedure in the chamber, a schematic diagram of a semiconductor structure of a high electron mobility transistor according to a first embodiment of the present invention, and a schematic diagram illustrating the diffusion behavior of metal dopants in the manufacturing method of the semiconductor structure according to the present invention.

As shown in FIGS. 2 to 5, the method for manufacturing a semiconductor structure according to the present invention is used to manufacture a semiconductor structure 1 of a high electron mobility transistor within a chamber 100. A first embodiment of the manufacturing method of the semiconductor structure includes steps S1 through S5. The steps of this method for manufacturing a semiconductor structure are described in detail below.

Step S1: depositing a barrier layer on a channel layer.

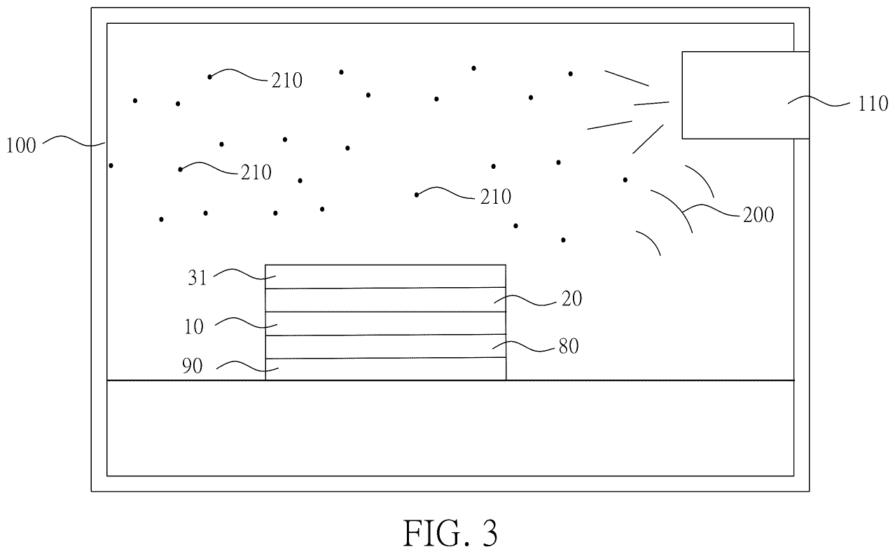

According to one specific embodiment of the present invention, as shown in FIGS. 3 to 5, a barrier layer 20 is deposited on a channel layer 10 within the chamber 100. The channel layer 10 is formed on a buffer layer 80 and a substrate 90. It should be noted that the substrate 90 and the buffer layer 80 disposed on the substrate 90 are part of the prior art, and since the buffer layer 80 and the substrate 90 are not the focus of the present improvement, their details will not be further described.

Step S2: depositing a doped control layer on the barrier layer.

As shown in FIGS. 3 to 5, a doped control layer 31 is deposited on the barrier layer 20. It should be noted that, in this step, the doped control layer 31 is an undoped gallium nitride (GaN) layer. According to one specific embodiment of the present invention, the thickness of the doped control layer 31 can be 20 nm.

Step S3: a preflow of a first doping source gas containing a metal dopant is performed in the chamber for a predetermined time.

As shown in FIG. 3, after depositing the doped control layer 31 on the barrier layer 20, a preflow of a first doping source gas 200 containing a metal dopant 210 is released into the chamber 100 for a predetermined time. The metal dopant is magnesium (Mg), the first doping source gas is Cp2Mg, and the predetermined time is from 10 seconds to 240 seconds. Through the preflow step, the concentration of magnesium (Mg) in the chamber 100 is increased to a range between 1E19 cm⁻³ and 3E19 cm⁻³, thereby ensuring that a sufficient hole concentration is available for the subsequent growth of the doped stabilization layer 32.

Step S4: Depositing a doped stabilization layer on the doped control layer, wherein both the doped stabilization layer and the doped control layer contain a metal dopant, wherein the metal dopant in the doped stabilization layer has a first doping concentration in a range from 1E19 cm⁻³ to 3E19 cm⁻³, and the metal dopant in the doped control layer has a second doping concentration in a range from 5E17 cm⁻³ to 1E19 cm⁻³.

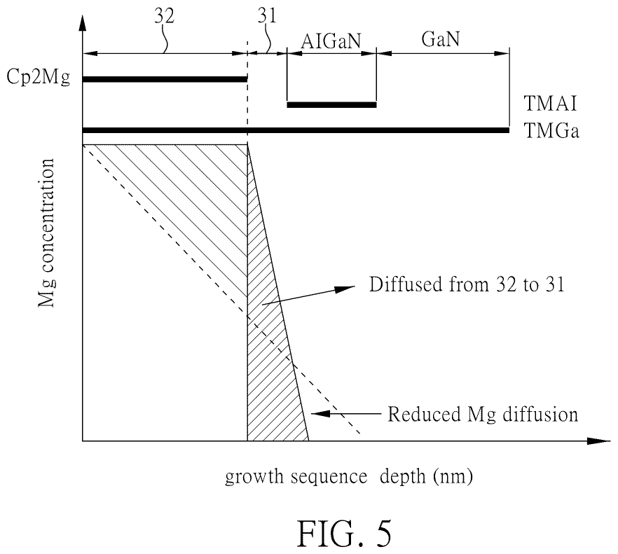

In this embodiment, since the metal dopant is magnesium (Mg) and the first doping source gas is Cp2Mg, the doped stabilization layer 32 becomes a p-type gallium nitride (p-GaN) layer. The thickness of the doped stabilization layer 32 is approximately 60 nm. However, other p-type metal dopants, such as iron (Fe) or zinc (Zn), are also applicable to the present invention. Furthermore, as shown in FIG. 5, by performing a preflow of the first doping source gas containing Mg inside the chamber 100 to elevate the Mg concentration to a range from 1E19 cm⁻³ to 3E19 cm⁻³ before deposition, the doped stabilization layer 32 can be grown with a sufficient Mg concentration to provide adequate hole carriers. Accordingly, the metal doping concentration in the doped stabilization layer 32 of this embodiment can be maintained near the predetermined target concentration. For example, the metal dopant in the doped stabilization layer 32 has a first doping concentration in a range from 1E19 cm⁻³ to 3E19 cm⁻³. In one embodiment of the present invention, the first doping concentration is from 1.0E19 cm⁻³ to 2E19 cm⁻³.

It should be noted that during the growth of the doped stabilization layer 32 on the doped control layer 31, as shown in FIG. 5, due to the diffusion effect of magnesium (Mg), Mg will diffuse from the doped stabilization layer 32 into the doped control layer 31 and the barrier layer 20, such that both the doped control layer 31 and the barrier layer 20 have a Mg doping concentration. However, because of the diffusion effect, the Mg doping concentration decreases as the distance from the doped stabilization layer 32 increases.

The second doping concentration of magnesium in the doped control layer 31 is lower than the first doping concentration of magnesium in the doped stabilization layer 32. Similarly, the third doping concentration of magnesium in the barrier layer 20 is lower than the second doping concentration of magnesium in the doped control layer 31. In this embodiment, the second doping concentration of the metal dopant in the doped control layer 31 is in a range from 5E17 cm⁻³ to 1E19 cm⁻³, and the third doping concentration of the metal dopant in the barrier layer 20 is in a range from 5E16 cm⁻³ to 5E17 cm⁻³. Since the doped control layer can effectively withstand the diffusion of the metal dopant from the doped stabilization layer, it reduces the impact of the dopant on the barrier layer, thereby improving the electrical characteristics of the high electron mobility transistor. Through this approach, the doping concentration of magnesium (Mg) in the barrier layer 20 is significantly reduced, resulting in substantial improvement in device performance.

Step S5: Depositing a gate metal on the doped stabilization layer to form the semiconductor structure.

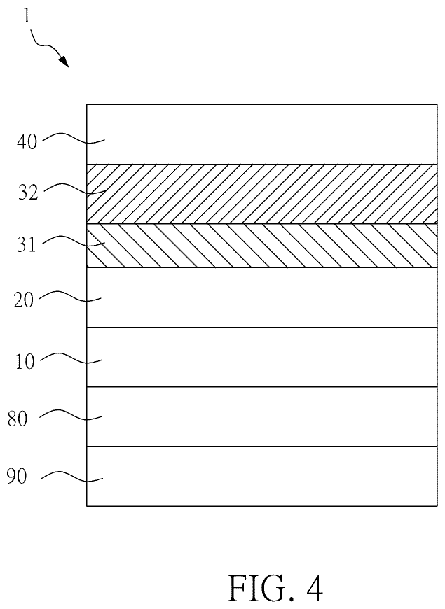

As shown in FIG. 4, a gate metal 40 is deposited on the doped stabilization layer 32 to form the semiconductor structure 1 of a high electron mobility transistor. It should be noted that the thicknesses of the doped stabilization layer 32 and the doped control layer 31 in the present invention are not limited to those of the above-described embodiment, as long as the thickness of the doped stabilization layer 32 is greater than the thicknesses of the doped control layer 31.

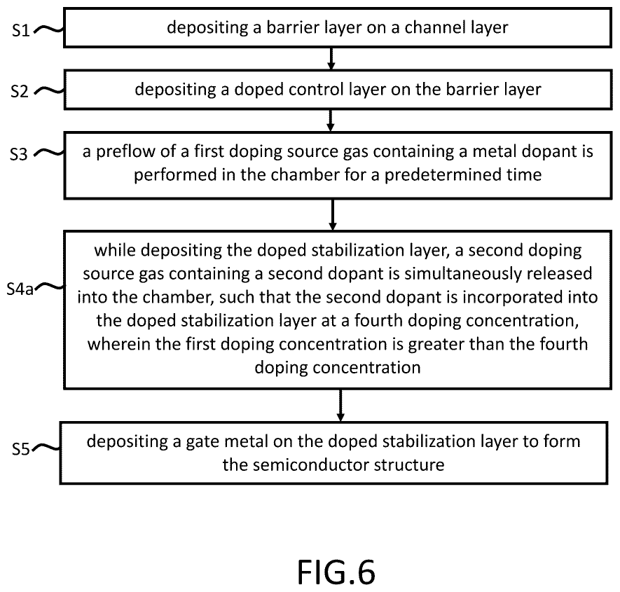

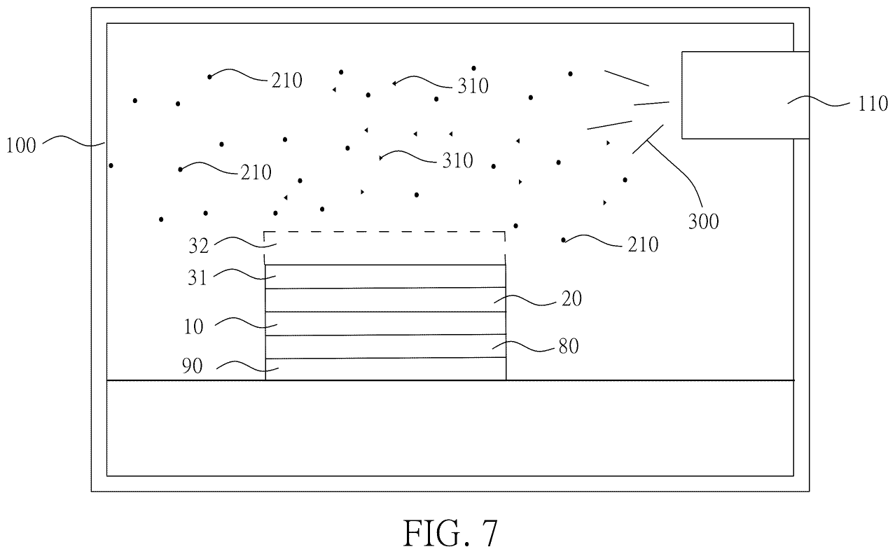

Please refer to FIG. 6 and FIG. 7, which illustrate the step flow diagram of the second embodiment of the semiconductor structure manufacturing method and a schematic diagram showing the supply of a second doping source gas into the chamber, according to the present invention. As shown in FIG. 6, the second embodiment of the semiconductor structure manufacturing method differs from the first embodiment in that it includes step S4a. The step S4a of the second embodiment will be described below.

Step S4a: While depositing the doped stabilization layer, a second doping source gas containing a second dopant is simultaneously released into the chamber, such that the second dopant is incorporated into the doped stabilization layer at a fourth doping concentration, wherein the first doping concentration is greater than the fourth doping concentration.

According to one embodiment of the present invention, as shown in FIG. 7, while the doped stabilization layer 32 is deposited on the doped control layer 31, a second doping source gas 300 containing a second dopant 310 is simultaneously released into the chamber 100. In this embodiment, the second dopant 310 is hydrogen, and the second doping source gas 300 is hydrogen gas. The reason for limiting the hydrogen doping concentration to be less than that of magnesium in the present invention is that, during the growth of the doped stabilization layer 32, if the hydrogen concentration in the doped stabilization layer exceeds that of magnesium, hydrogen passivation of magnesium may occur. This prevents magnesium from contributing a sufficient number of holes in the doped stabilization layer 32, thereby adversely affecting the threshold voltage (Vth) characteristics of the semiconductor structure 1 of the high electron mobility transistor. Therefore, to ensure that the hole concentration in the doped stabilization layer 32 falls within a range of 5E16 cm⁻³ to 1E18 cm⁻³, the doping concentration (i.e., the fourth doping concentration) of the second dopant (hydrogen) in the doped stabilization layer 32 must be lower than the doping concentration (i.e., the first doping concentration) of the metal dopant (magnesium) in the doped stabilization layer 32.

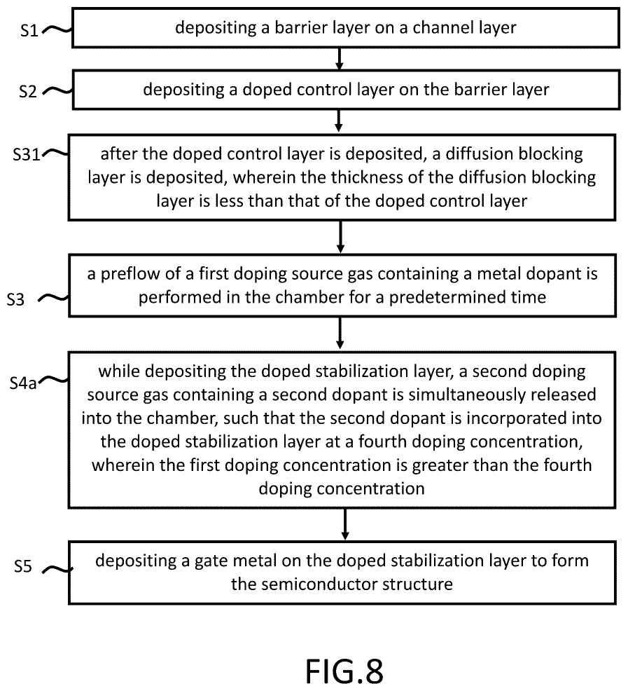

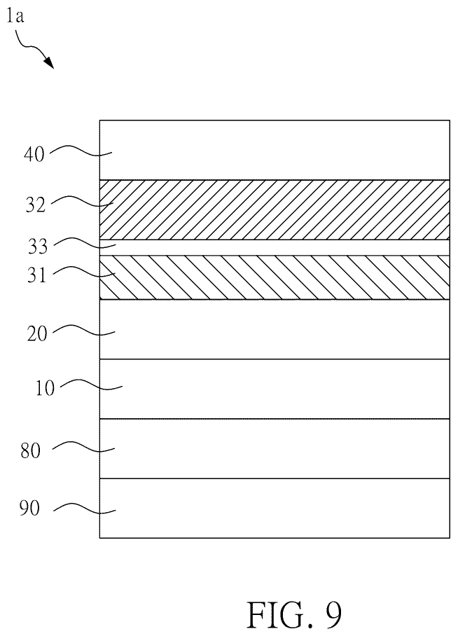

Please refer to FIG. 8 and FIG. 9, which respectively illustrate a step flow diagram of a third embodiment of the method for manufacturing the semiconductor structure of the present invention and a schematic diagram of a second embodiment of the semiconductor structure of a high electron mobility transistor according to the present invention. As shown in FIG. 8, the third embodiment of the method for manufacturing the semiconductor structure of the present invention differs from the second embodiment in that it includes step S31. Step S31 of the third embodiment of the manufacturing method of the present invention is described below.

Step S31: After the doped control layer is deposited, a diffusion blocking layer is deposited, wherein the thickness of the diffusion blocking layer is less than that of the doped control layer.

In the present embodiment, after the doped control layer 31 is deposited on the barrier layer 20, a diffusion blocking layer 33 is deposited on the doped control layer 31. Subsequently, step S3 is performed, in which Cp2Mg containing Mg doping is released into the chamber 100 for 10 to 240 seconds (preflow process). Thereafter, a doped stabilization layer 32 is deposited on the diffusion blocking layer 33, and a gate metal 40 is deposited on the doped stabilization layer 32. By means of the diffusion blocking layer 33, the diffusion of Mg from the doped stabilization layer 32 into the doped control layer 31 and the barrier layer 20 is reduced, thereby forming a semiconductor structure 1a of a high electron mobility transistor, as shown in FIG. 9. According to one embodiment of the present invention, the diffusion blocking layer 33 is an aluminum gallium nitride (AlGaN) layer, and the thickness of the diffusion blocking layer 33 is less than or equal to 4 nm.

Please refer again to FIG. 4 and FIG. 8, which respectively illustrate the first embodiment and the second embodiment of the semiconductor structure of a high electron mobility transistor according to the present invention.

As shown in FIG. 4, the semiconductor structure 1 of the high electron mobility transistor (HEMT) according to the first embodiment includes a channel layer 10, a barrier layer 20, a doped control layer 31, a doped stabilization layer 32, and a gate metal 40. The channel layer 10 is disposed on a buffer layer 80 and a substrate 90. The barrier layer 20 is disposed on the channel layer 10. The doped control layer 31 is disposed on the barrier layer 20. The doped stabilization layer 32 is disposed on the doped control layer 31. The gate metal 40 is disposed on the doped stabilization layer 32.

In this embodiment, the thickness of the doped stabilization layer 32 is 60 nm, and the thickness of the doped control layer 31 is 20 nm. It should be noted that the thicknesses of the doped stabilization layer 32 and the doped control layer 31 are not limited to those specified in the above embodiment, as long as the thickness of the doped stabilization layer 32 is greater than that of the doped control layer 31.

Both the doped stabilization layer 32 and the doped control layer 31 of the semiconductor structure 1 of the HEMT include metal dopant. The metal dopant in the doped stabilization layer 32 has a first doping concentration ranging from 1E19 cm⁻³ to 3E19 cm⁻³. In one embodiment, the first doping concentration ranges from 1.0E19 cm⁻³ to 2E19 cm⁻³. The metal dopant in the doped control layer 31 has a second doping concentration ranging from 5E17 cm⁻³ to 1E19 cm⁻³. The metal dopant in the barrier layer 20 has a third doping concentration ranging from 5E16 cm⁻³ to 5E17 cm⁻³.

It should be noted that, in this embodiment, the metal dopant is magnesium (Mg), and therefore, the doped stabilization layer 32 is a p-type gallium nitride (pGaN) layer. However, other p-type metal dopants, such as iron (Fe) or zinc (Zn), are also applicable. Furthermore, prior to the growth of the doped stabilization layer 32 and before the metal dopant enters the doped control layer 31, the doped control layer 31 in this embodiment is an undoped gallium nitride layer (undoped GaN layer).

Due to the diffusion effect of magnesium (Mg) during the manufacturing process, magnesium diffuses from the doped stabilization layer 32 into the doped control layer 31 and the barrier layer 20. This results in both the doped control layer 31 and the barrier layer 20 of the HEMT's semiconductor structure 1 containing a concentration of magnesium doping. Since the metal dopant in the doped control layer 31 and the barrier layer 20 results from magnesium diffusion, the second doping concentration of magnesium in the doped control layer 31 and the third doping concentration of magnesium in the barrier layer 20 are both lower than the first doping concentration.

According to one embodiment of the present invention, the semiconductor structure 1 of the high electron mobility transistor further includes a second dopant, which is present in the doped stabilization layer 32 at a fourth doping concentration, wherein the fourth doping concentration is less than the first doping concentration. In one embodiment of the present invention, the second dopant is hydrogen. In the semiconductor structure 1 of the high electron mobility transistor, if the hydrogen concentration exceeds the magnesium concentration, hydrogen may passivate the magnesium, thereby preventing magnesium from contributing holes in the semiconductor structure 1 of the high electron mobility transistor. This would adversely affect the threshold voltage (Vth) characteristics of the semiconductor structure 1. Therefore, to ensure that the hole concentration of the doped stabilization layer 32 is in a range from 5E16 cm⁻³ to 1E18 cm⁻³, the doping concentration (fourth doping concentration) of the second dopant (hydrogen) in the doped stabilization layer 32 must be lower than the doping concentration (first doping concentration) of the metal dopant (magnesium) in the doped stabilization layer 32.

As shown in FIG. 9, the difference between the semiconductor structure 1a of the high electron mobility transistor in the second embodiment and the semiconductor structure 1 of the high electron mobility transistor in the first embodiment lies in that the semiconductor structure 1a of the high electron mobility transistor further includes a diffusion blocking layer 33. The diffusion blocking layer 33 is disposed between the doped control layer 31 and the doped stabilization layer 32 to reduce the concentration of the metal dopant (e.g., magnesium) diffusing from the doped stabilization layer 32 into the doped control layer 31 and the barrier layer 20. According to one embodiment of the present invention, the diffusion blocking layer 33 is an aluminum gallium nitride (AlGaN) layer, and the thickness of the diffusion blocking layer 33 is less than or equal to 4 nm.

The present invention utilizes a preflow process to rapidly raise the concentration of the metal dopant 210 (e.g., magnesium) in the chamber 100 to a range between 1E19 cm⁻³ and 3E19 cm⁻³ prior to the growth of the doped stabilization layer 32, thereby facilitating the subsequent growth of the doped stabilization layer 32 and improving the electrical characteristics of the semiconductor structures 1 and 1a of the high electron mobility transistor. Since the doped control layer can effectively accommodate diffusion of the metal dopant from the doped stabilization layer, it reduces the impact of the dopant on the barrier layer and maintains the electrical performance of the semiconductor structures 1 and 1a of the high electron mobility transistor.

It should be noted that many of the above-mentioned embodiments are given as examples for description, and the scope of the present disclosure should be limited to the scope of the following claims and not limited by the above embodiments.

What is claimed is:

1. A method for manufacturing a semiconductor structure of a high electron mobility transistor (HEMT) in a chamber, comprising:
depositing a barrier layer on a channel layer
depositing a doped control layer on the barrier layer;
performing a preflow in the chamber of a first doping source gas containing a metal dopant for a predetermined time;
after the predetermined time, depositing a doped stabilization layer on the doped control layer, wherein both the doped stabilization layer and the doped control layer contain the metal dopant,
wherein the metal dopant in the doped stabilization layer has a first doping concentration in a range from 1E19 cm⁻³ to 3E19 cm⁻³, and
wherein the metal dopant in the doped control layer has a second doping concentration in a range from 5E17 cm⁻³ to 1E19 cm⁻³; and
depositing a gate metal on the doped stabilization layer to form the semiconductor structure of the high electron mobility transistor.

2. The method as claimed in claim 1, wherein the first doping source gas is Cp2Mg, the metal dopant is magnesium (Mg), and the predetermined time is from 10 seconds to 240 seconds.

3. The method as claimed in claim 1, wherein before the preflow of the first doping source gas containing the metal dopant is performed in the chamber for the predetermined time of time, the doped control layer is an undoped gallium nitride (GaN) layer.

4. The method as claimed in claim 1, further comprising:
after depositing the doped control layer, depositing a diffusion blocking layer, wherein a thickness of the diffusion blocking layer is less than the thickness of the doped control layer; and
depositing the doped stabilization layer on the diffusion blocking layer.

5. The method as claimed in claim 1, wherein the barrier layer contains the metal dopant at a third doping concentration ranging from 5E16 cm⁻³ to 5E17 cm⁻³.

6. The method as claimed in claim 1, further comprising:
while depositing the doped stabilization layer, simultaneously releasing a second doping source gas into the chamber, the second doping source gas containing a second dopant,
wherein the doped stabilization layer has a fourth doping concentration of the second dopant; and
wherein the first doping concentration is greater than the fourth doping concentration.

7. The method as claimed in claim 6, wherein the second dopant is hydrogen.

8. The method as claimed in claim 1, wherein a hole concentration of the doped stabilization layer is in a range from 5E16 cm⁻³ to 1E18 cm⁻³.

9. A semiconductor structure of a high electron mobility transistor, manufactured by the method of claim 1, wherein the thickness of the doped stabilization layer is greater than the thickness of the doped control layer.

10. The semiconductor structure as claimed in claim 9, further comprising a diffusion blocking layer disposed between the doped control layer and the doped stabilization layer, wherein the thickness of the diffusion blocking layer is less than the thickness of the doped control layer.

11. The semiconductor structure as claimed in claim 9, wherein the barrier layer contains the metal dopant at a third doping concentration ranging from 5E16 cm⁻³ to 5E17 cm⁻³.

12. The semiconductor structure as claimed in claim 9, wherein a hole concentration of the doped stabilization layer is in a range from 5E16 cm⁻³ to 1E18 cm⁻³.

13. The semiconductor structure as claimed in claim 9, further comprising a second dopant, wherein the doped stabilization layer further has a fourth doping concentration of the second dopant, and the first doping concentration is greater than the fourth doping concentration.

14. The semiconductor structure as claimed in claim 13, wherein the second dopant is hydrogen.
